(19) United States
(12) Patent Application Publication
(10) Pub. No.: US 2013/0113810 A1
(43) Pub. Date: May 9, 2013

(54) SIDEWALL SPACERS ALONG CONDUCTIVE LINES

(71) Applicants: Chok Wah Ho, Milpitas, CA (US); Fan Zhong, Fremont, CA (US)

(72) Inventors: Chok Wah Ho, Milpitas, CA (US); Fan Zhong, Fremont, CA (US)

(73) Assignee: QUALCOMM MEMS Technologies, Inc., San Diego, CA (US)

(21) Appl. No.: 13/289,935

(22) Filed: Nov. 4, 2011

(51) Int. Cl. G06F 13/00; H01L 31/18; H05K 3/10; H01L 31/0232

(52) U.S. Cl. 345/520; 257/435; 438/69; 29/846; 257/E31.127

(57) ABSTRACT

Systems, methods and apparatus are provided for electromechanical systems devices having a sidewall spacer along at least one sidewall of a conductive line. An electromechanical systems device can include a sidewall spacer along at least one sidewall of a conductive line under a movable layer. The sidewall spacer can be sloped such that the sidewall spacer has a decreasing width away from a substrate under the movable layer. The conductive line can be configured to route an electrical signal to the electromechanical systems device. In some implementations, a black mask structure of an electromechanical systems device can include the conductive line.

This disclosure relates to electrical devices having crossing conductive lines, such as bussing lines or interconnects, and methods for fabricating the same.

### DESCRIPTION OF THE RELATED TECHNOLOGY

Electromechanical systems (EMS) include devices having electrical and mechanical elements, actuators, transducers, sensors, optical components (such as mirrors and optical film layers) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

Electromechanical systems can include an electromechanical systems device with an air gap under a movable electrode layer. The air gap can be formed by removing sacrificial material under the movable layer. The shape of the movable layer can be affected by the topography of underlying structures, such as the sacrificial material, the stationary electrode and/or bussing lines.

Similarly, the topography created by an underlying conductive line can create electrical shorts (such as sidewall stringers) in overlying conductive lines in a variety of contexts such as stacked bussing lines or interconnects for MEMS, NEMS or integrated circuits.

### SUMMARY

The systems, methods and devices of the disclosure each have several innovative aspects, no single one of which is solely responsible for the desirable attributes disclosed herein.

One innovative aspect of the subject matter described in this disclosure can be implemented in an apparatus that includes an electromechanical systems device. The electromechanical systems device includes a substrate and a conductive line over the substrate. The electromechanical systems device also includes a movable layer farther from the substrate than the conductive line. In addition, the electromechanical systems device includes a sidewall spacer along at least one sidewall of the conductive line, in which the sidewall spacer is sloped such that the sidewall spacer has a decreasing width away from the substrate.

The electromechanical systems device can include an air gap between the movable layer and the conductive line. In some implementations, the electromechanical systems device can include an active interferometric modulator pixel in which less than about 1.5% of light is reflected in a dark state occurring when the movable layer collapses on the air gap. The movable layer can include a reflective surface configured to collapse on a gap.

The conductive line can be configured to route an electrical signal to the electromechanical systems device. Alternatively or additionally, the conductive line can be part of an interferometric black mask.

The width of the sidewall spacer can decrease linearly away from the substrate.

The electromechanical systems device can also include a support structure positioned over the conductive line, and the support structure supporting the movable layer. In some implementations, the movable layer can be shaped to be self-supporting.

The electromechanical systems device can also include a stand-off configured to prevent a backplate from contacting the movable layer. Alternatively or additionally, the electromechanical systems device can also include a buffer formed over the sidewall spacer, in which the buffer and the sidewall spacer each include one or more of silicon oxide, silicon oxynitride, and silicon nitride.

Another innovative aspect of the subject matter described in this disclosure can be implemented in an apparatus that includes an electromechanical systems device. The electromechanical systems device includes a conductive line formed over a substrate. The electromechanical systems device also includes a movable layer suspended above the substrate. The movable layer has a first region over the conductive line and a second region not over the conductive line, in which the first region is adjacent to the second region. In addition, the electromechanical systems device includes means for smoothing a transition in the movable layer between the first region and the second region. The means for smoothing is located along an edge of the conductive line.

The movable layer can include a mirror layer configured to collapse a gap under the movable layer. Alternatively or additionally, the second region can be an active part of an interferometric modulator and the first region can include a black mask.

The means for smoothing can avoid a kink in the transition in the movable layer between the first region and the second region. The means for smoothing can create a slope in the movable layer in the transition from the second region to the first region, in which a distance between the movable layer and the substrate increases in the transition from the second region to the first region. The means for smoothing can include a sidewall spacer along at least one sidewall of the conductive line.

Another innovative aspect of the subject matter described in this disclosure can be implemented in a method of forming an electromechanical systems device. The method includes forming a sidewall spacer along at least one sidewall of a conductive line, the conductive line over a substrate. The method also includes forming a sacrificial layer over the conductive line and the sidewall spacer. In addition, the method includes forming a movable layer of the electromechanical systems device over the sacrificial layer.

The sidewall spacer can be formed while patterning an other feature of the electromechanical systems device. The other feature of the electromechanical systems device can include a stand-off that extends above the movable layer. Alternatively or additionally, the other feature of the electromechanical systems device can be formed over the conductive line. Forming the sidewall spacer can include depositing a blanket layer of material from which the sidewall spacer and the other feature will be formed, and using a mask to cover a location of the other feature while leaving a location of the sidewall spacer exposed by the mask.

The method can also include removing the sacrificial layer to create a gap under the movable layer. Alternatively or additionally, method can include forming a buffer layer over the conductive line and the sidewall spacer prior to forming the sacrificial layer. In some instances, the method can include forming a black mask including an absorber layer, a dielectric layer, and the conductive line.

Another innovative aspect of the subject matter described in this disclosure can be implemented in an apparatus that includes a substrate, a first line formed over the substrate, sidewall spacers along sidewalls of the first line, and a second line non-parallel to the first line, in which the second line is conformally over the first line.

The first line can be a conductive line. A conformal dielectric can be included between the first line and the second line. The first line can be in electrical contact with the second line.

The apparatus can include a first plurality of lines and a second plurality of lines non-parallel to the first plurality of lines, in which the first plurality of lines include the first line and the second plurality of lines include the second line. Each line of the first plurality of lines can be a metal line and each line of the second plurality of lines can be a metal line. Each line of the second plurality of lines can be spaced apart from an adjacent line of the second plurality of lines by less than approximately 5 μm.

The sidewall spacers can include metal. In some instances, the first line can have a height of at least approximately 1,500 Å.

Yet another innovative aspect of the subject matter described in this disclosure can be implemented in a method of forming a stack of conductive lines. The method can include forming a first conductive line over a substrate, forming sidewall spacers along sidewalls of the first conductive line, and forming a second conductive line crossing over the first conductive line, in which the second conductive line is conformal.

The method can also include depositing a conformal dielectric layer over the first conductive line. Alternatively or additionally, the method can include forming an opening in the conformal dielectric conformal layer to expose a top surface of the first conductive line.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show an example electromechanical systems device with a kink in the movable layer.

FIGS. 10A-10G show examples of cross-sectional schematic illustrations of various stages in a method of making interferometric modulator devices with sidewall spacers along sidewalls of a conductive line, according to some implementations.

FIG. 11 shows an example of a flow diagram illustrating a manufacturing process for an electromechanical systems device having a sidewall spacer along a sidewall of a conductive line under a movable layer, according to some implementations.

FIG. 12 shows an example of an electromechanical systems device with a sidewall spacer along a sidewall of a conductive line under a movable layer, according to some implementations.

FIG. 13A shows an example of a schematic plan view of an interferometric modulator array that includes the interferometric modulators of FIG. 10G.

FIG. 13B is an example of a schematic cross section taken along lines 13B-13B of FIG. 13A.

FIG. 14A shows an example of a top isometric view of intersections of two conformal conductive lines formed over a lower conductive line.

FIGS. 14B-E show different examples of schematic cross sections of the intersection of conductive lines according to some implementations.

FIG. 15 shows an example of a flow diagram illustrating a manufacturing process for conductive lines having sidewall spacers along sidewalls of the conductive lines, according to some implementations.

FIGS. 16A and 16B show examples of system block diagrams illustrating a display device that includes a plurality of interferometric modulators.

Like reference numbers and designations in the various drawings indicate like elements.

### DETAILED DESCRIPTION

The following description is directed to certain implementations for the purposes of describing the innovative aspects of this disclosure. However, a person having ordinary skill in the art will readily recognize that the teachings herein can be applied in a multitude of different ways. The described implementations may be implemented in any device or system that can be configured to display an image, whether in motion (e.g., video) or stationary (e.g., still image), and whether textual, graphical or pictorial. More particularly, it is contemplated that the described implementations may be included in or associated with a variety of electronic devices such as, but not limited to: mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (i.e., e-readers), computer monitors, auto displays (including odometer and speedometer displays, etc.), cockpit controls and/or displays, camera view displays (such as the display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (such as in electromechanical systems (EMS), microelectromechanical systems (MEMS) and non-MEMS applications), aesthetic structures (e.g., display of images on a piece of jewelry) and a variety of EMS devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes and electronic test equipment. Thus, the teachings are not intended to be limited to the implementations depicted solely in the Figures, but instead have wide applicability as will be readily apparent to one having ordinary skill in the art.

Electronic devices and EMS devices can be provided with tapered sidewall spacers along a conductive line, thereby smoothing topography of overlying layers, including sacrificial layers, dielectrics, and conductors. According to some implementations, a black mask of an electromechanical systems device can include a conductive line and a sidewall spacer is formed along a sidewall of the black mask stack. The conductive line can route electrical signals to the electromechanical systems device, for example, to actuate a movable layer between an actuated position and a non-actuated position. The overlying conductor can be a movable layer in the electromechanical systems device, as well as intermediate layers between the movable layer and the conductive line.

Particular implementations of the subject matter described in this disclosure can be implemented to realize one or more of the following potential advantages. The sidewall spacers can smooth the topography created by the underlying conductive lines. For crossing conductive lines (e.g., bussing lines or interconnects), the sidewall spacers can alleviate cracking in intervening insulators and resultant leakage paths between bottom conductive lines and top conductive lines, thus improving yield. The sidewall spacers can also reduce leakage paths among top conductive lines through stringer shorts compared to lines formed conformally over the bottom conductive lines without the use of the sidewall spacers. The methods and structures described herein can reduce a kink or cusp in a movable layer of an electromechanical systems device. Dark state performance in optical electromechanical systems devices, such as IMODs, can be improved by using the devices described herein. More specifically, in some implementations, white rings around pixels and/or subpixels can be reduced and/or eliminated from the dark state of an IMOD device. Moreover, the sidewall spacers can be formed while forming other features on a substrate, so no additional masks may be needed. The methods of manufacturing electromechanical systems devices described herein are scalable to greater thicknesses of conductive lines and can be applied to a number of different manufacturing processes and/or architectures of microelectronic devices (e.g., MEMS or integrated circuits).

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity. One way of changing the optical resonant cavity is by changing the position of the reflector.

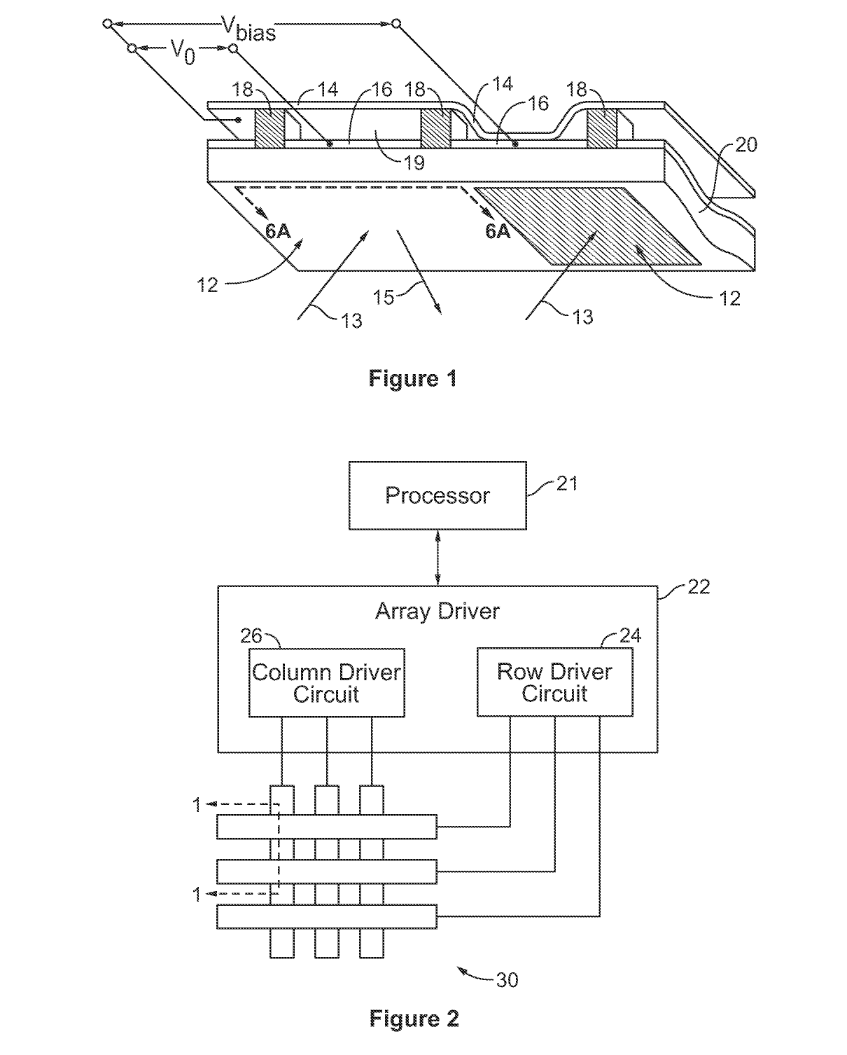

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, absorbing and/or destructively interfering light within the visible range. In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, such as chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and electrical conductor, while different, electrically more conductive layers or portions (e.g., of the optical stack 16 or of other structures of the IMOD) can serve to bus signals between IMOD pixels. The optical stack 16 also can include one or more insulating or dielectric layers covering one or more conductive layers or an electrically conductive/optically absorptive layer.

In some implementations, the layer(s) of the optical stack 16 can be patterned into parallel strips, and may form row electrodes in a display device as described further below. As will be understood by one having ordinary skill in the art, the term “patterned” is used herein to refer to masking as well as etching processes. In some implementations, a highly conductive and reflective material, such as Al, may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 μm, while the gap 19 may be less than <10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, a voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

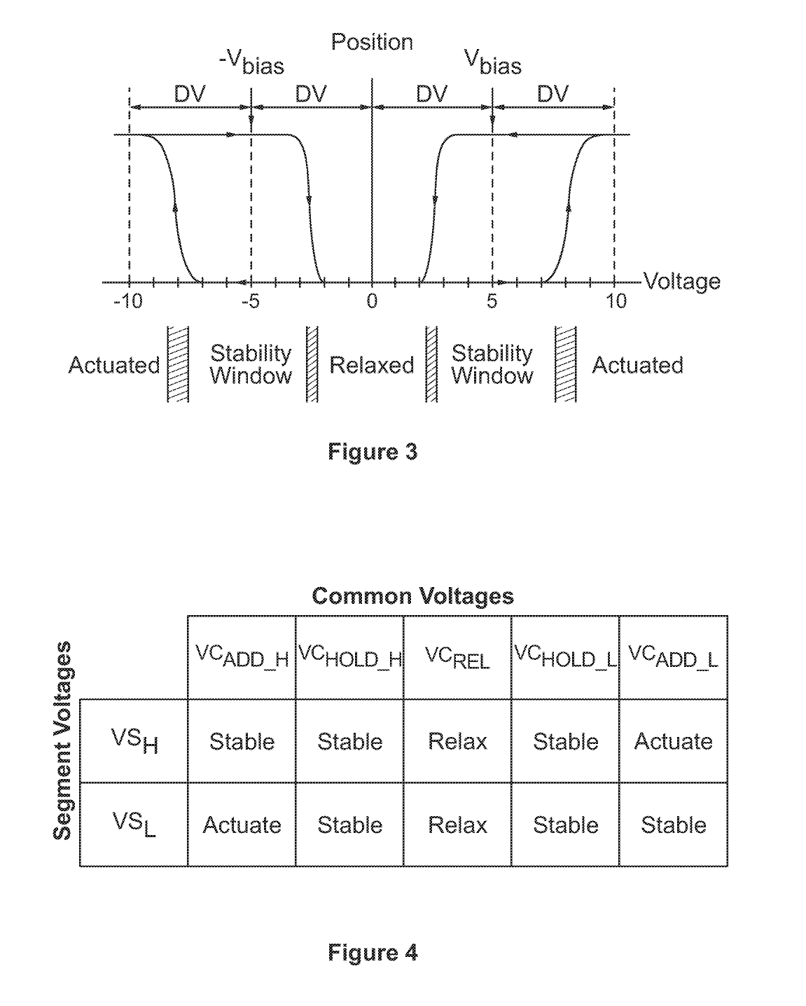

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, for example, a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

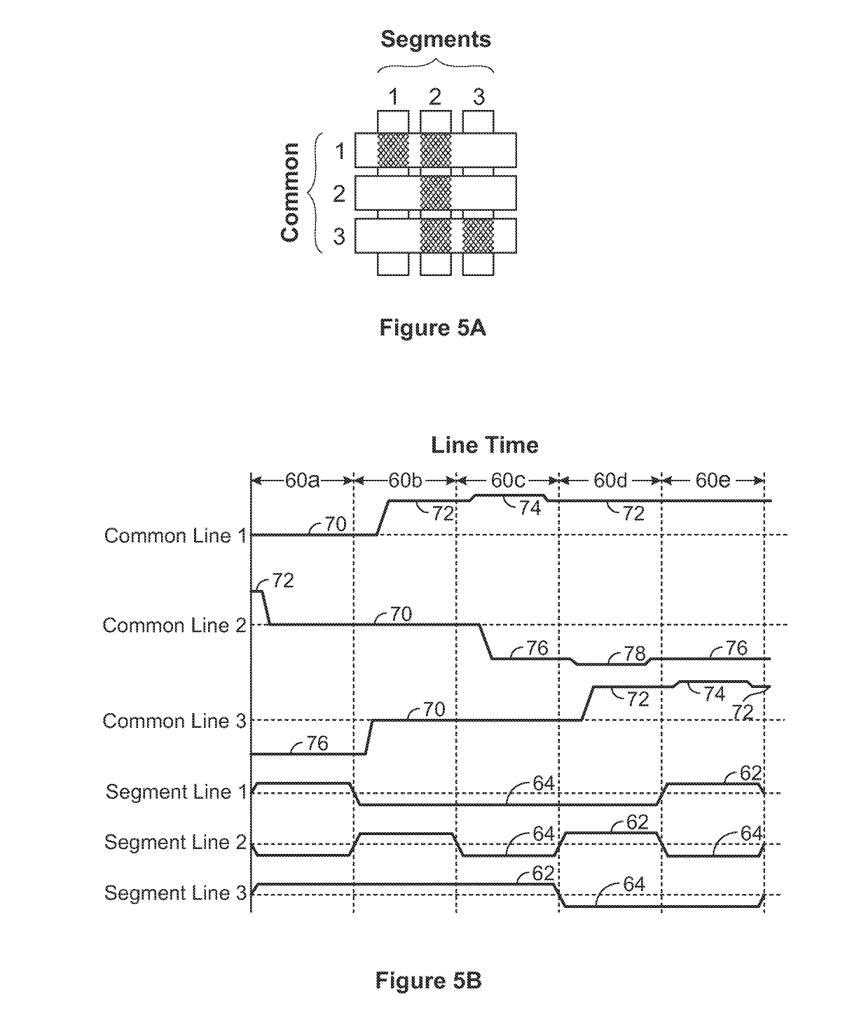

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may use, in one example implementation, about a 10-volt potential difference to cause the movable reflective layer, or mirror, to change from the relaxed state to the actuated state. When the voltage is reduced from that value, the movable reflective layer maintains its state as the voltage drops back below, in this example, 10 volts, however, the movable reflective layer does not relax completely until the voltage drops below 2 volts. Thus, a range of voltage, approximately 3 to 7 volts, in this example, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about, in this example, 10 volts, and pixels that are to be relaxed are exposed to a voltage difference of near zero volts. After addressing, the pixels can be exposed to a steady state or bias voltage difference of approximately 5 volts in this example, such that they remain in the previous strobing state. In this example, after being addressed, each pixel sees a potential difference within the “stability window” of about 3-7 volts. This hysteresis property feature enables the pixel design, such as that illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

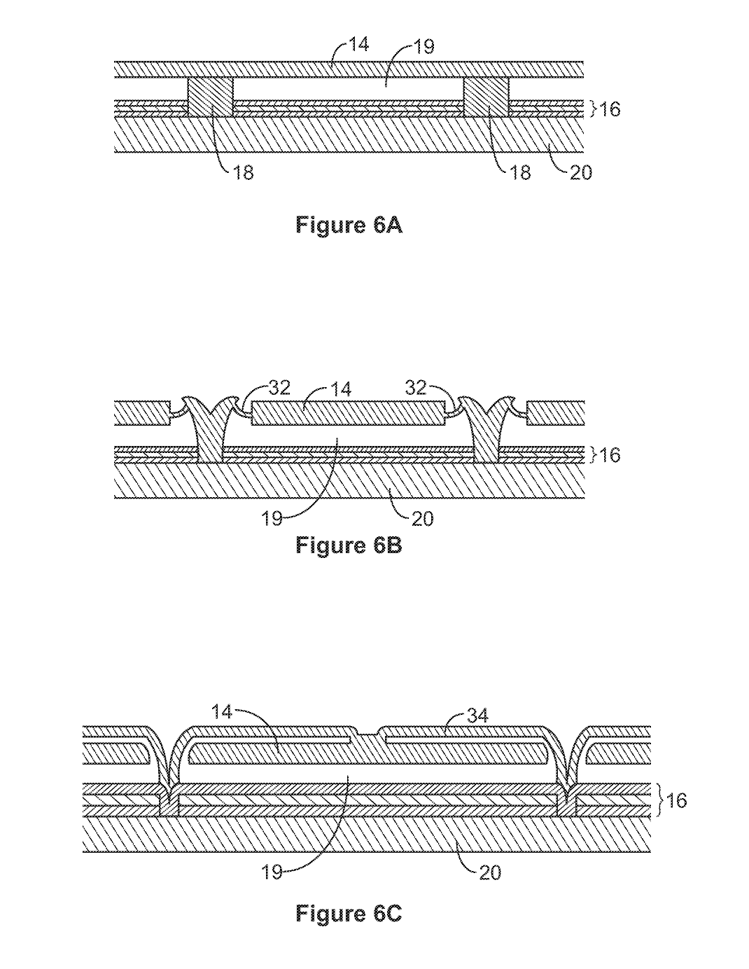

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be understood by one having ordinary skill in the art, the “segment” voltages can be applied to either the column electrodes or the row electrodes, and the “common” voltages can be applied to the other of the column electrodes or the row electrodes.

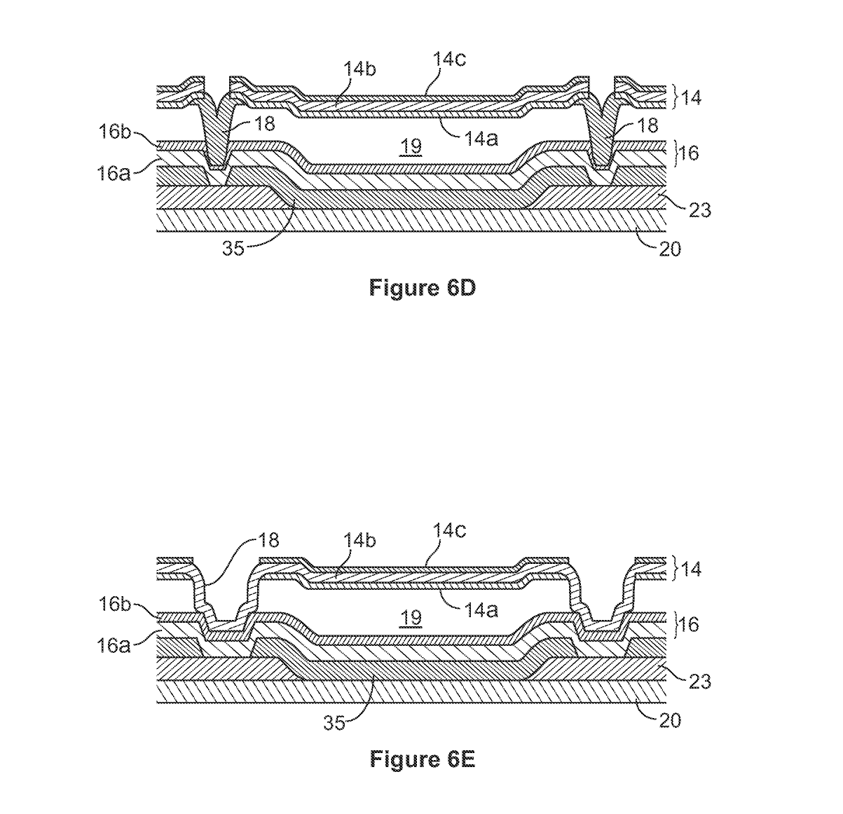

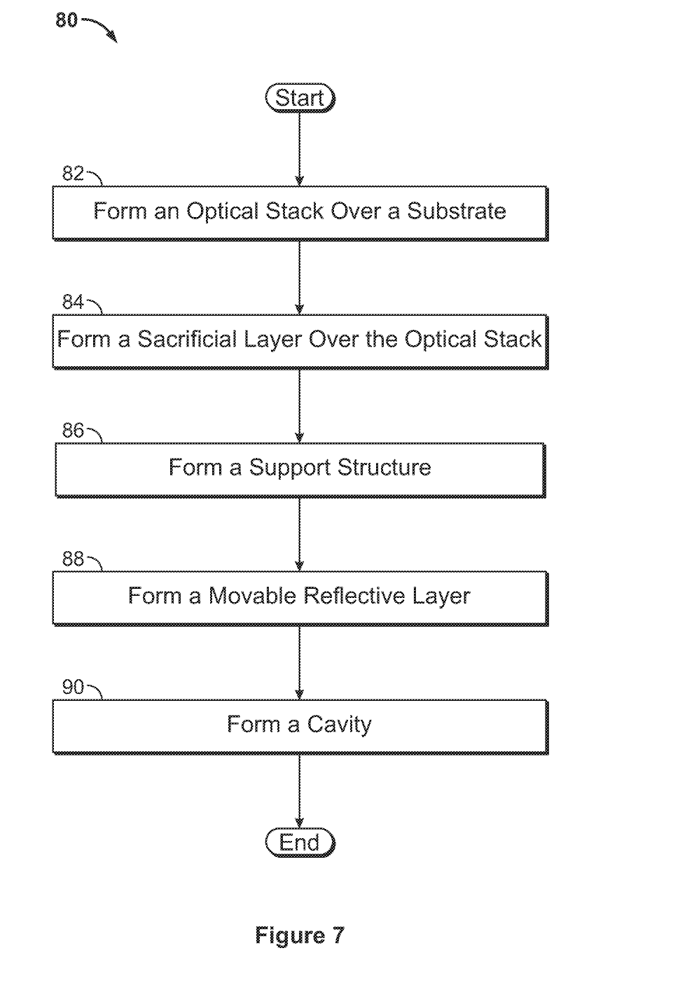

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator pixels (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which produce the same polarity potential difference across the modulators. In some other implementations, signals can be used which alternate the polarity of the potential difference of the modulators from time to time. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to a 3×3 array, similar to the array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, for example, a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a characteristic threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

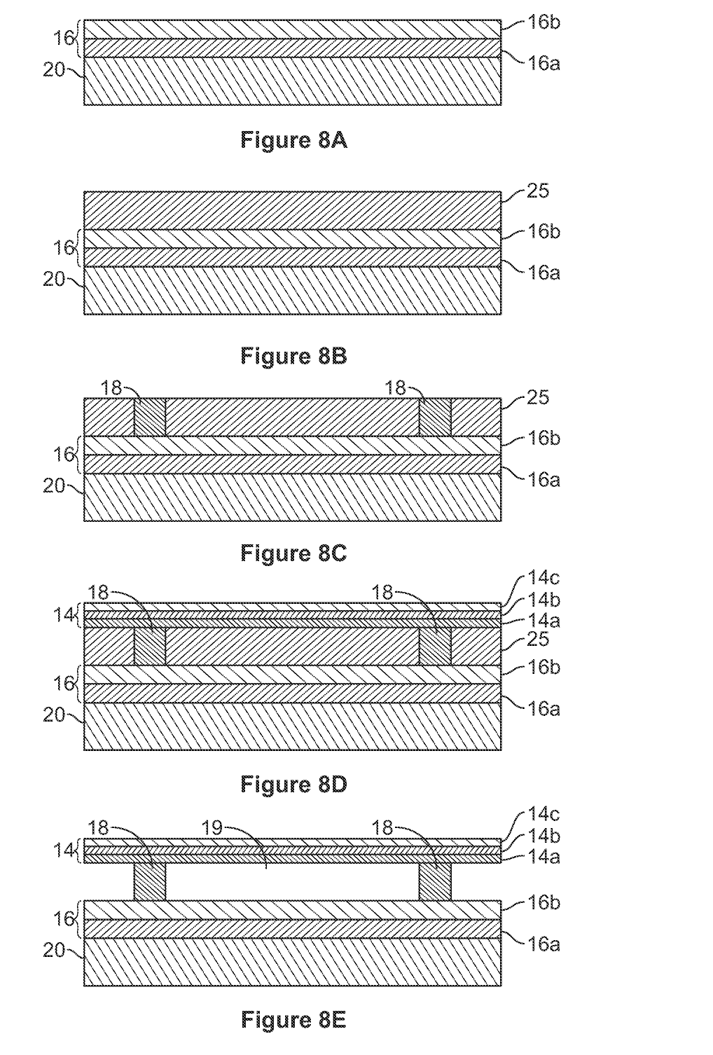

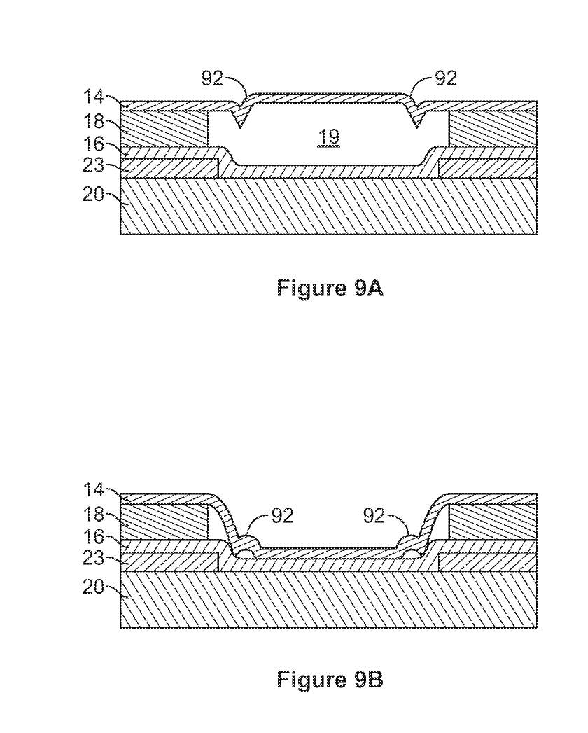

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In this example, the movable electrode and the mechanical layer are one and the same. In FIG. 6B, the movable reflective layer 14 of each IMOD is generally square or rectangular in shape and attached to supports 18 at or near the corners, on tethers 32. The mechanical layer and the movable electrode can also one and the same in this example. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as supports or support posts 18. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another. The deformable layer 34 can also be referred to as a mechanical layer. Either the deformable layer 34 or the reflective layer 14 could be considered movable layers.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiOₓN_{y}) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, for example, an Al alloy with about 0.5% copper (Cu), or another reflective metallic material. Employing conductive layers 14a and 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (such as between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a SiO₂ or SiON layer that serves as a dielectric layer, and an Al alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the Al alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a dielectric layer 35 can serve to generally electrically isolate electrodes or conductor(s) in the optical stack 16 (such as the absorber layer 16a) from the conductive layers in the black mask 23.

FIG. 6E shows another example of an IMOD, where the movable reflective layer 14 is self supporting. In contrast with FIG. 6D, the implementation of FIG. 6E does not include separately formed support posts. Instead, the movable reflective layer 14 contacts the underlying optical stack 16 at multiple locations to create integrated supports 18, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer. In the examples of FIGS. 6D and 6E, the entire movable reflective layer 14 or any one or a subset of its sub-layers 14a, 14b and 14c could be considered a mechanical layer or a movable layer. In some implementations, the optical absorber 16a is an order of magnitude (ten times or more) thinner than the movable reflective layer 14. In some implementations, optical absorber 16a is thinner than reflective sub-layer 14a.

In implementations such as those shown in FIGS. 6A-6E, the IMOD displays function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, for example, patterning.

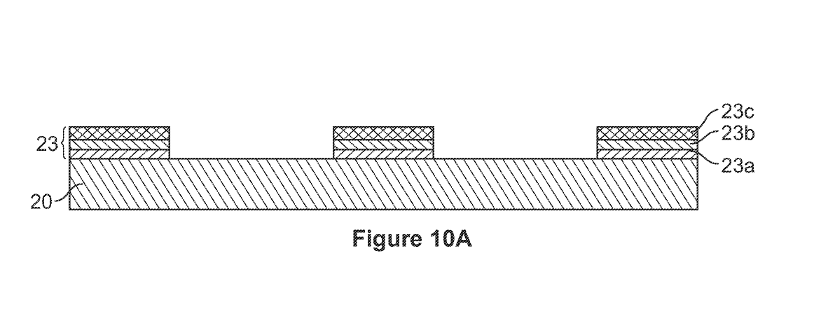

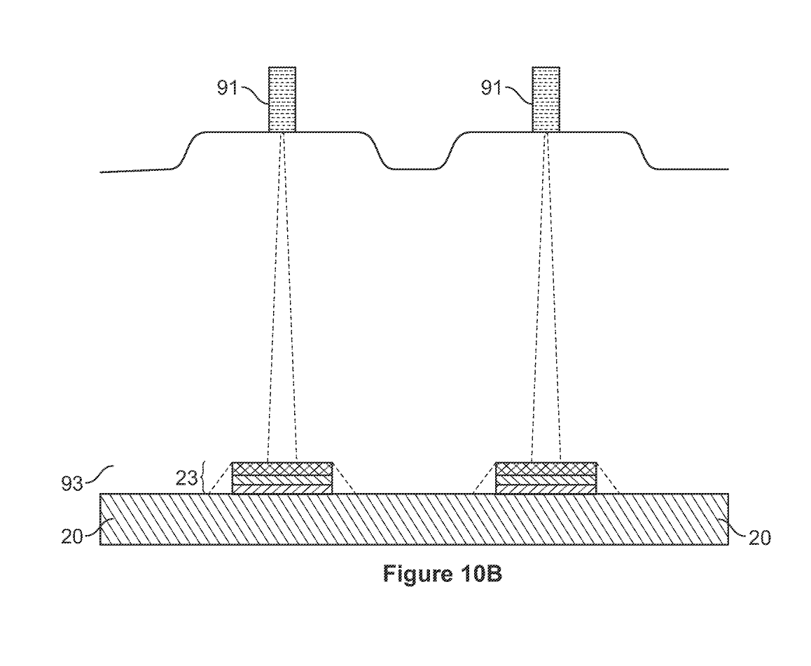

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture an electromechanical systems device such as interferometric modulators of the general type illustrated in FIGS. 1 and 6A-6E. The manufacture of an electromechanical systems device can also include other blocks not shown in FIG. 7. With reference to FIGS. 1, 6A-6E, and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, such as cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and electrically conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display. It is noted that FIGS. 8A-8E may not be drawn to scale. For example, in some implementations, one of the sub-layers of the optical stack, the optically absorptive layer, may be very thin, although sub-layers 16a, 16b are shown somewhat thick in FIGS. 8A-8E.

The process 80 continues at block 84 with the formation of a sacrificial layer 25 over the optical stack 16. The sacrificial layer 25 is later removed (see block 90) to form the cavity 19 and thus the sacrificial layer 25 is not shown in the resulting interferometric modulators illustrated in FIGS. 1 and 6A-6E. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material, such as molybdenum (Mo) or amorphous silicon (a-Si), in a thickness selected to provide, after subsequent removal, a gap or cavity 19 (see also FIGS. 1, 6A-6E, and 8E) having a desired design size. Deposition of the sacrificial material may be carried out using deposition techniques such as physical vapor deposition (PVD, which includes many different techniques, such as sputtering), plasma-enhanced chemical vapor deposition (PECVD), thermal chemical vapor deposition (thermal CVD), or spin-coating.

The process 80 continues at block 86 with the formation of a support structure such as post 18 as illustrated in FIGS. 1, 6A, 6D, and 8C. The formation of the post 18 may include patterning the sacrificial layer 25 to form a support structure aperture, then depositing a material (such as a polymer or an inorganic material such as silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a masking and etching process, but also may be performed by alternative patterning methods.

The process 80 continues at block 88 with the formation of a movable reflective layer or membrane such as the movable reflective layer 14 illustrated in FIGS. 1, 6A-6E, and 8D. The movable reflective layer 14 may be formed by employing one or more deposition steps including, for example, reflective layer (such as Al, Al alloy, or other reflective layer) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b and 14c as shown in FIG. 8D. In some implementations, one or more of the sub-layers, such as sub-layers 14a and 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, such as cavity 19 as illustrated in FIGS. 1, 6A-6E, and 8E. The cavity 19 may be formed by exposing the sacrificial material 25 (deposited at block 84) to an etchant. For example, an etchable sacrificial material such as Mo or amorphous Si may be removed by dry chemical etching, by exposing the sacrificial layer 25 to a gaseous or vaporous etchant, such as vapors derived from solid XeF₂, for a period of time that is effective to remove the desired amount of material. The sacrificial material is typically selectively removed relative to the structures surrounding the cavity 19. Other etching methods, such as wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

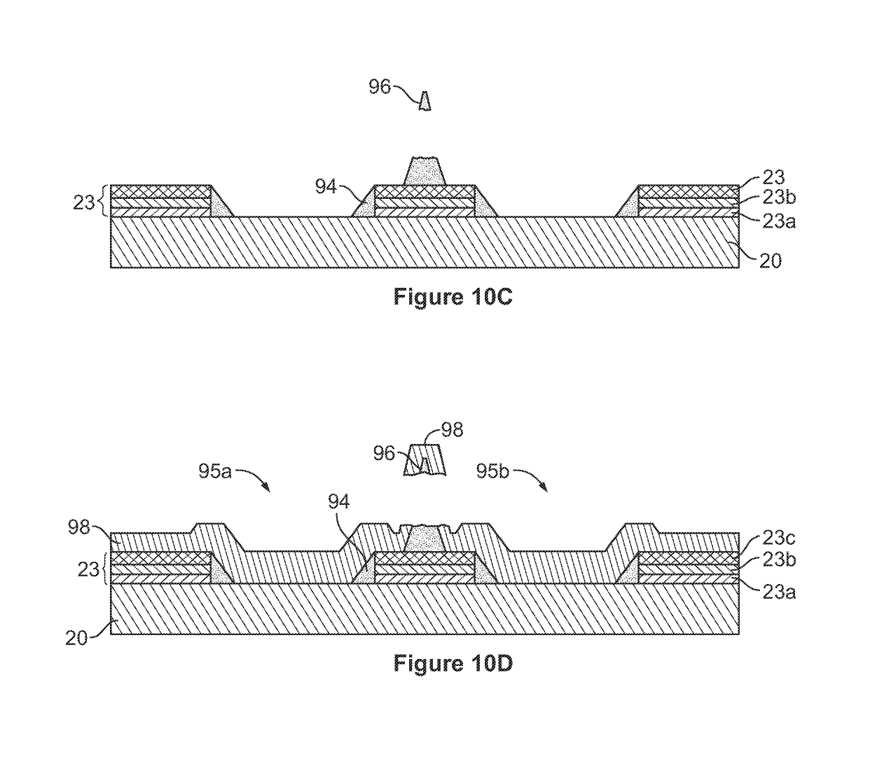

FIGS. 9A and 9B show an example electromechanical systems device with a kink in the movable layer. Any of the movable layers described herein can include a movable reflective layer 14, for example, as shown in FIGS. 6A-E. Non-uniformities in the movable layer, such as kinks 92, can result from forming one or more layers with poor step coverage over the underlying topography, particularly conductors such as PVD metallic layers. As more layers are formed over the layer with poor step coverage, such non-uniformities in the movable layer can become more pronounced. The kink 92 shown in FIG. 9A can result from, for example, poor step coverage of layers formed over a feature of the electromechanical systems device. For example, a black mask structure 23 of an optical electromechanical device, such as an IMOD, can create a large step for subsequent depositions to conform. The black mask structure 23 can include any combination of features described above with reference to black mask structures. For example, the black mask structure can serves as an electrical bussing line. An etalon black mask can include a reflector (such as Al), an optical cavity layer (such as SiO₂ or other dielectric) and a semitransparent optical absorber layer (such as MoCr). Whereas the reflector can be quite thin if it only serves the black mask reflector function (for example, 500 Å of Al or Al alloy can be sufficient to be reflective), it tends to be considerably thicker to additionally serve a signal bussing function (>1,000 Å, for example, 5,000 Å of Al or Al alloy). Subsequent depositions, particularly PVD, poorly conform and can create reentrant profiles or kinks 92.

The kink 92 can prevent the movable layer from fully actuating. For example, as shown in FIG. 9B, portions of the movable layer do not come into contact with the optical stack 16 near the black mask structure 23 when the movable layer 14 is actuated to collapse the gap 19. As a result, a peripheral portion of the movable layer 14 may not come into physical contact with a lower electrode, such as a layer in an optical stack 16 for an IMOD implementation, when actuated. In some optical implementations, this can result in reduced dark state performance. In some instances, when a portion of the movable layer does not come into physical contact with the lower electrode, visible white rings around pixels can be formed near the periphery of the pixel where the kink 92 forms (near the black mask 23) when the pixel is meant to be in a dark state during activation. These effects can be problematic in a number of implementations, including optical (such as IMOD) and non-optical electromechanical systems device (such as RF switches).

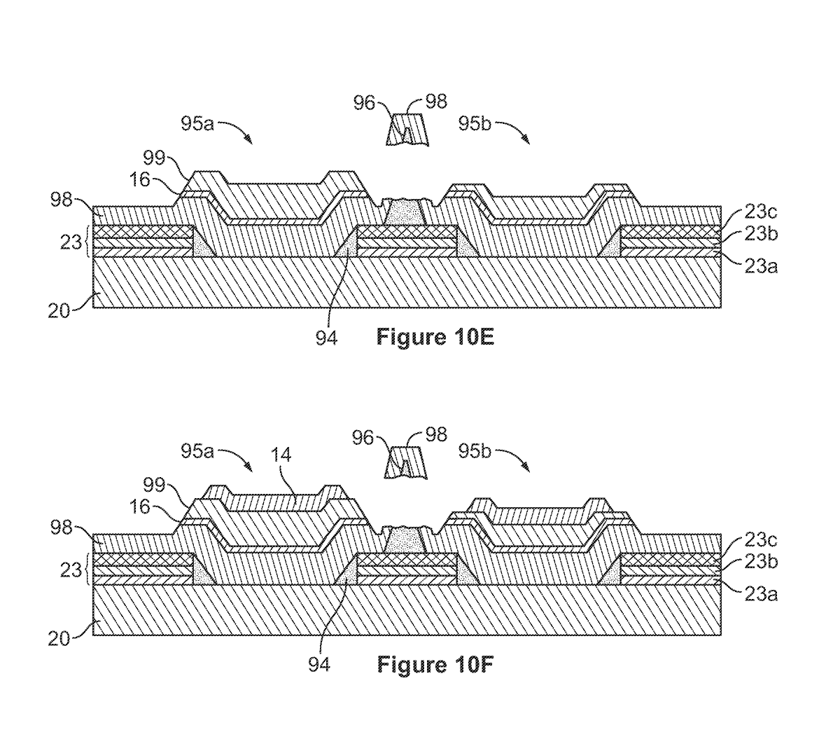

FIGS. 10A-10G show examples of cross-sectional schematic illustrations of various stages in a method of making interferometric modulator devices with sidewall spacers along sidewalls of a conductive line, according to some implementations. While particular structures and processes are described as suitable for an interferometric modulator (IMOD) implementation, it will be understood that for other electromechanical systems implementations (e.g., electromechanical switches, optical filters, accelerometers, etc.), different materials can be used or parts modified, omitted, or added. Additionally, in some interferometric modulator display applications, the drawings may not reflect an accurate scale. For example, the horizontal distance between mechanical layers of adjacent rows of devices may be about 3-10 μm, and the lengths or widths of the gaps 19 for individual electromechanical systems devices can be 10's to 100's of microns in the horizontal direction, and the gap heights in active regions can be less than 10 microns. For example, gap heights for IMOD devices can range from 150 nm (0.15 μm) to 600 nm (0.6 μm). As another example, the distance between pixels or mechanical layers in adjacent devices can be about 100 μm in certain radio frequency MEMS applications (e.g., switches, switched capacitors, varactors, resonators, etc.) while each mechanical layer can be about 30-50 μm long.

FIG. 10A illustrates cross sections of portions of two IMOD devices during fabrication. The cross section shown in FIG. 10A includes a black mask structure 23 formed over a portion of a substrate 20. The width of the black mask structure 23 can be, for example, about 5 μm in some implementations. The black mask structure 23 can appear dark as viewed through a substrate, such as the transparent substrate 20. In some implementations, the substrate 20 includes glass. The black mask structure 23 can include any combination of features of the black mask structures described above, for example, with reference to FIGS. 6D and 6E. In some implementations, the black mask structure 23 is an etalon or interferometric black mask that includes a semireflective optical absorber layer 23a formed of, for example, MoCr, an optical gap layer 23b formed of, for example, SiO₂ or SiON or other dielectric, and a reflective layer 23c. The optical absorber layer 23a, the dielectric layer 23b, and the reflective layer 23c can have thicknesses in the range of about 30-80 Å, 250-1,000 Å, and 500-10,000 Å, respectively, for example. The reflective layer 23c can serve as a reflector and/or a bussing layer. The reflective layer 23c can include Al or Al alloys such as AlCu, AlSl, AlNd, the like, or any combination thereof. When serving as a conductive line to bus signals, the reflective layer 23c tends to be a thicker layer of metal (such as 3,000-10,000 Å), which can exacerbate topography issues.

Referring back to FIGS. 9A and 9B, a movable layer can include a kink due to cusping when formed over high topologies in layers formed below the movable layer. Such a kink can be located at a transition between a first region over a conductive line, such as the black mask 23 and particularly the reflective sub-layer 23c thereof, and a second region adjacent the first region that is not over the conductive line. To smooth a transition in the movable layer between the first region and the second region, a means for smoothing can be provided. The means for smoothing can reduce cusping or other effects in the formation of layers over the conductive line. In some implementations, the means for smoothing is located along an edge of the conductive line. For instance, the means for smoothing can include sidewall spacers along sidewalls of the conductive line.

Referring to FIG. 10B, a blanket layer 93 is formed over the substrate 20. Features, such as spacers and/or sidewall spacers, can be formed from the blanket layer 93. A mask 91 (such as a photoresist or hard mask) can cover portions of the blanket layer 93, which are indicated by dashed lines in FIG. 10B. Portions of the blanket layer 93 that are not covered by the mask 91 can be removed to define the features.

Referring to FIG. 10C, sidewall spacers 94 are formed along sidewalls of conductive lines. For example, the sidewall spacer 94 can be formed along some or all of the black mask structure 23, including the reflective sub-layer 23c that can serve as a bussing line. The sidewall spacers 94 can be sloped. For example, the sidewall spacer 94 can have a decreasing width away from the substrate. In some implementations, the width of the sidewall spacer 94 decreases linearly away from the substrate, as shown; in other implementations the taper produces a curved outer surface. The sidewall spacers 94 can be formed from a variety of materials. For instance, the sidewall spacers 94 can include SiO₂, SiN, SiOₓN_{y}, and/or other dielectric material. In another implementation, the sidewall spacers 94 can be conductive and thus bolster conductivity of the conductive line. With the sidewall spacers 94, suitable step coverage of layers formed over the conductive line (e.g., the reflective sub-layer 23c that doubles as a bussing layer) can be realized despite a large thickness for the conductive material in order to serve a bussing or interconnect function.

In the implementation shown in FIG. 10C, the sidewall spacers 94 can be formed while patterning an other feature of an electromechanical systems device. For example, the sidewall spacers 94 can be formed while patterning a stand-off 96 over the black mask 23. To illustrate that the stand-off 96 is significantly taller than the sidewall spacers 94 and other features of the electromechanical systems device, a broken line is shown in FIGS. 10C-10G. The stand-off 96 can serve to control a separation between the substrate 20 and a subsequently laminated or attached backplate, particularly in a touch screen implementation. In some implementations, a blanket layer 93 of material from which the sidewall spacer 94 and the other feature (such as the stand-off 96) will be formed is deposited, and a mask covers a location of the other feature while leaving a location of the sidewall spacer 94 exposed by the mask. In implementations where all of the blanket layer other than the stand-off 96 is to be removed, an overetch may be employed to ensure that no sidewall spacers are left on, for example, a sidewall of black mask 23. However, rather than the normal overetch, the directional etch that patterns the stand-off 96 (or other feature) under the mask can be timed to leave the sidewall spacers 94. If any of the blanket material remains in undesired locations, a short isotropic etch can remove it without excess removal of the stand-off 96 or sidewall spacers 94.

Referring to FIG. 10D, a buffer layer 98 can be formed over the black mask structure 23. There are a variety of ways to form the buffer layer 98 including, for example, chemical vapor deposition (CVD) or physical vapor deposition (PVD). The buffer layer 98 can be an oxide. In some implementations, the buffer layer 98 can include SiO₂, SiN and/or SiOₓN_{y}. According to some implementations, the buffer layer 98 can be formed of substantially the same material as the sidewall spacers 94. Nevertheless, the buffer layer 98 and the sidewall spacers 94 can be structurally distinguished. For example, performing an etch decoration (such as dilute HF die) will reveal an interface between the sidewall spacers 94 and the buffer layer 98 even if they are formed of the same oxide. The sidewall spacers 94 can reduce cusping in the buffer layer 98 and overlying layers. In particular, the portion of the buffer layer 98 over the sidewall spacers 94 can have a slope that monotonically increases, in some implementations.

Referring to FIG. 10E, an optical stack 16 can be formed over the buffer layer 98, and sacrificial material 99 can be formed over the substrate 20 and the optical stack 16. The optical stack 16 can include any combination of features of optical stacks described herein, for example, as described above with reference to FIGS. 1 and 6A-6E, including relatively thin conductor(s) to serve as a stationary electrode for the electromechanical systems device. The sacrificial material 99 includes one or more temporary layers, and at least a portion of the sacrificial material 99 can later be removed to form a gap under the movable layer (which will be formed later). The sacrificial material can include more than one layer, or include a layer of varying thickness, to aid in the formation of a display device having a multitude of resonant optical gaps with different gap heights. For example, in a color IMOD array, multiple different IMODs are each provided with, for example, one of three different gap sizes, where each gap size represents a different reflected color. The formation of sacrificial material 99 over the substrate 20 and the optical stack 16 can include, for example, deposition of a fluorine-etchable material such as molybdenum (Mo), tungsten (W), amorphous silicon (Si) or metal silicides, in a thickness selected to provide, after subsequent removal, a gap with a desired height. Deposition of sacrificial material 99 over the optical stack 16 can be carried out using deposition techniques such as physical vapor deposition (PVD, for example, sputtering), plasma-enhanced chemical vapor deposition (PECVD), or thermal chemical vapor deposition (thermal CVD).

Referring still to FIG. 10E, the sacrificial material 99 can be formed over a portion of a first electromechanical systems device 95a and over a portion of a second electromechanical systems device 95b. As illustrated, the first electromechanical systems device 95a and the second electromechanical systems device 95b are adjacent to each other. The sacrificial material 99 over a first region of the first electromechanical systems device 95a can have a first thickness that is different from a second thickness of the sacrificial material 99 over a second region of the second electromechanical systems device 95b. In the cross section illustrated in FIG. 10E, the thickness of sacrificial material 99 over the first electromechanical systems device 95a can be suitable for removal to define a high gap subpixel (for example, for reflecting blue in the relaxed position) and the thickness of sacrificial material and over the second electromechanical systems device 95b can be suitable for removal to define a mid gap subpixel (for example, for reflecting red in the relaxed position). Although not shown, sacrificial material having a third thickness suitable for a low gap subpixel (for example, for reflecting green in the relaxed position) can be formed over a third electromechanical systems device.

In some implementations, three sacrificial layers are deposited and patterned. A high gap device can have sacrificial material having a thickness that includes three layers of sacrificial material. A mid gap device can have sacrificial material having a thickness that includes two of the three layers of sacrificial material. A low gap device can have sacrificial material having a thickness that includes one of the three layers of sacrificial material. One having ordinary skill in this field will appreciate that other ways of producing different sacrificial material thicknesses for producing different electromechanical system device gap sizes can be used. The topography underlying the sacrificial material can have a more pronounced effect on thicker sacrificial layers and layers subsequently formed over the thicker sacrificial layers. Accordingly, the sidewall spacer 94 can have a more pronounced effect reducing undesired features (such as a kink) for movable layer in a high gap device than in a mid gap or low gap device.

FIG. 10F illustrates forming a movable layer, such as movable reflective layer 14, over the sacrificial material 99. The movable layer can include any combination of features of the movable layers described herein, for example, as shown in and described in reference to FIGS. 1 and 6A-6E. For example, the movable layer may include a reflective sub-layer, a support layer, and/or a conductive layer, for example, as illustrated in the implementations shown in FIGS. 6D and 6E. The movable layer can be formed by a variety of techniques, such as atomic layer deposition (ALD). In some IMOD implementations, the thickness of the movable layer can be selected to be in the range of about 200-800 Å. For example, the thickness of the movable layer can be selected in the range of about 600-800 Å for a low gap device, about 400-600 Å for a mid gap device, and about 200-400 Å for a high gap device. Different thicknesses of the movable layer over different gap sizes can produce different stiffnesses and aid in normalizing actuation voltage. It will be understood that the movable layer can include a variety of layers, depending upon the electromechanical systems device functions. For example, the movable layer can be made flexible and conductive, or include flexible and conductive layers, to function as a movable electrode, for example, as shown in FIG. 6A.

Although the description herein may refer to forming a desired topography of a movable layer for illustrative purposes, it will be understood that any combination of features described in connection with a movable layer can also be implemented in connection with a mechanical layer and/or a movable reflective layer. In some implementations, the movable layer can be a mechanical layer (as shown, for example, in FIGS. 6A, 6B, 6D, and 6E). In other implementations, the movable layer can be separate from the mechanical layer (for example, a movable layer is suspended from a mechanical layer in the implementation of FIG. 6C).

As shown in FIG. 10G, an additional portion of some movable layers can be formed. This can result in some movable layers having different thicknesses and consequently different stiffnesses. As also shown in FIG. 10G, the sacrificial material 99 can be removed to form a gap 19 in active regions under the movable layer. The gap 19 can be an air gap. For example, some implementations of the optical stack 16 include a 50 Å MoCr layer, a 330 Å SiO₂ layer, and a 100 Å aluminum oxide layer (Al₂O₃). In an implementation of an optical stack 16, the first electromechanical systems device 95a can be a high gap device (e.g., a second-order blue IMOD). The gap 19 of the first electromechanical systems device 95a can have a height selected from the range of about 300 nm to 600 nm, for example about 350 nm. The second electromechanical systems device 95b can be a mid gap device (e.g., a red IMOD). The gap 19 of the second electromechanical systems device 95b can have a height selected from the range of about 200 nm to 300 nm, for example about 230 nm. Other electromechanical systems devices can be included in an array that includes the first electromechanical systems device 95a and the second electromechanical systems device 95b. Some of the other electromechanical systems devices can be low gap devices (e.g., a first-order green IMOD). The gap 19 of a low gap device can have a height selected from the range of about 150 nm to 200 nm, for example about 190 nm. It is understood that the particular gap heights, and the associated colors, also depend upon the design of the optical stack 16 and the movable reflective layer 14, including the thicknesses and materials used. It will be understood that other gap sizes may be suitable for other types of electromechanical systems devices.

The movable layer can define a post 18 to suspend the movable layer above the substrate 20 in an unactuated position. While the illustrated movable layer is a self-supporting movable reflective layer 14, any combination of features described with reference to FIGS. 10A-10F can be implemented in connection with other support structures, such as the posts 18 in FIGS. 6A-6D. For example, support structures that are separate from the movable layer can suspend the movable layer above the substrate 20 in an unactuated position, in some implementations.

As shown in FIGS. 10F and 10G, the movable layer (i.e., the movable reflective layer 14) can have a transition between the first region over a conductive line 23c and a second region adjacent the first region that is not over the conductive line 23c. With the sidewall spacer 94, the transition can slope upward from the second region to the first region. Such a slope can be monotonically increasing, in some implementations. With the upward slope in the movable layer in the transition, the movable layer can more easily physically contact a lower surface, such as a surface of the optical stack 16, when actuated compared to a device with a kink, such as the device shown in FIGS. 9A and 9B.

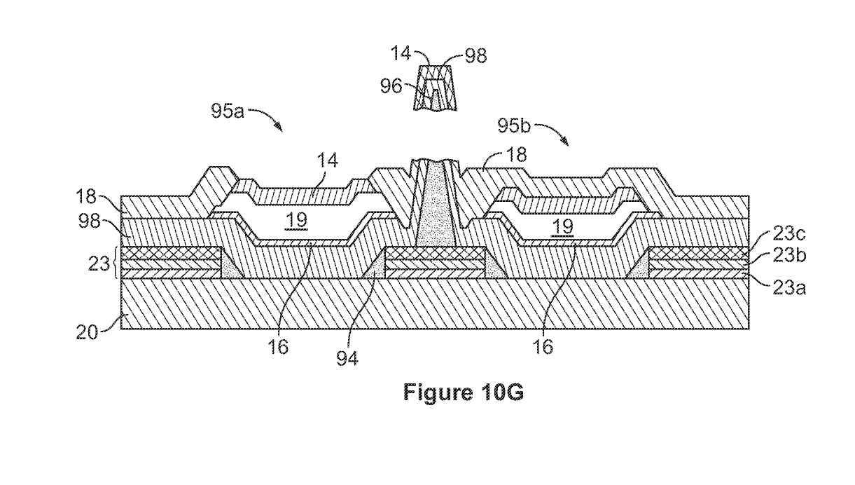

FIG. 11 shows an example of a flow diagram illustrating a manufacturing process 100 for an electromechanical systems device having a sidewall spacer along a sidewall of a conductive line under a movable layer, according to some implementations. The conductive line can be included in a black mask structure. In some implementations, the process 100 can include forming a black mask including an absorber layer, a dielectric layer, and the conductive line. Sidewall spacers are formed along sidewalls of a conductive line at block 102. The sidewall spacer can be formed along some or all of a sidewall of a conductive line.

In some implementations, the sidewall spacers are formed while patterning an other feature of the electromechanical systems device, such as a post or stand-off over a conductive line. For example, the sidewall spacers can be formed while forming a stand-off that extends above the movable layer (which will be formed later). Such a stand-off can be formed over a black mask stack. The other feature can be formed of substantially the same material as the sidewall spacers. According to some implementations, forming the sidewall spacers includes depositing a blanket layer of material from which the sidewall spacers and the other feature will be formed and using a mask to cover a location of the other feature while leaving a location of the sidewall spacers exposed by the mask. Sidewall spacers can be formed, for example, by careful timing of the etch while the other feature (such as stand-offs for a backplate) are being patterned, without requiring a separate deposition, mask or etch. In some implementations, the sidewall spacer can be formed via chemical vapor deposition (CVD) and subsequent directional etch.

At block 104, a layer of sacrificial material is formed over the conductive line and the sidewall spacers. One or more sacrificial layers can be deposited over the sidewall spacers. Additionally, in some implementations, the process 100 can include forming a buffer layer over the conductive line and the sidewall spacers prior to forming the sacrificial layer. The topography of each layer deposited over the sidewall spacers, such as the sacrificial layer(s), can be smoothed by the sidewall spacers relative to deposition over the conductive line with vertical walls and no sidewall spacers, particularly for thick conductive lines over 1000 Å. With the sidewall spacers, kinks in subsequently formed layers can be reduced and/or avoided.

A movable layer is formed over the sacrificial layer at block 106. The movable layer can be a movable reflective layer and/or a mechanical layer. Some or all of the sacrificial material can be removed to create a gap under the movable layer, in some implementations. The gap can be an optical gap that can determine a color of a pixel/subpixel in some implementations, such as IMOD implementations.

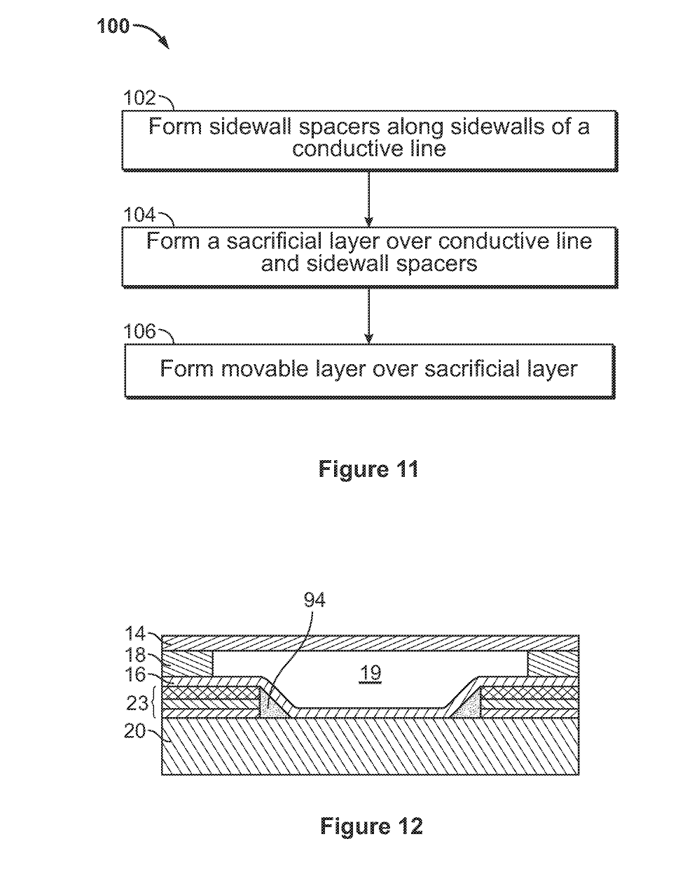

FIG. 12 shows an example of an electromechanical systems device with a sidewall spacer 94 along a sidewall of a conductive line under a movable layer, according to some implementations. The electromechanical systems device can include a substrate 20 and a movable layer, such as a movable reflective layer 14, over the substrate 20. The electromechanical systems device includes a conductive line under the movable layer. The conductive line can be directly under the movable layer or there can be one or more intermediate elements between the conductive line and the movable layer. The movable layer can be farther from the substrate 20 than the conductive line. In some implementations, the conductive layer can be included in the black mask structure 23. The conductive line can be configured to route electrical signals to the electromechanical systems device. The electrical signals can toggle the movable layer between an unactuated position suspended above a lower surface (such as a stationary electrode formed by a MoCr layer in the optical stack 16) by a gap 19 and an actuated position in which the gap 19 is collapsed.

The gap 19 can be an air gap. In an active interferometric modulator implementation, a low amount of visible light, e.g., less than about 3%, 1.75%, 1.5%, 1.25%, or 1.0% may be reflected in a dark state occurring when the movable reflective layer 14 is actuated to collapse the gap 19. The electromechanical systems device can include a support structure, such as a post 18, positioned over the conductive line. The support structure can support the movable layer in the unactuated position when the movable layer is spaced from a lower surface by the gap 19. In some implementations, the movable layer can itself define the support structure, such that the movable layer can be said to be self-supporting.

A sidewall spacer 94 along at least one sidewall of the conductive line under the movable layer can be sloped such that the sidewall spacer 94 has a decreasing width away form the substrate 20. Sidewall spacers 94 can be along sidewalls of conductive lines on opposing sides of the electromechanical systems devices. The width of the sidewall spacer 94 can decrease linearly away from the substrate 20, in some implementations. In some implementations, an other sidewall spacer along at least one sidewall of an other conductive line can also be included. The other conductive line can be vertically displaced from the conductive line. For instance, the other conductive line can be a stacked bus line. Alternatively or additionally, the other conductive line can be horizontally displaced from the conductive line.

Although not illustrated in FIG. 12, the electromechanical systems device can include a buffer formed over the sidewall spacer 94. In some implementations, the buffer and the sidewall spacer 94 are formed of substantially the same material, for example, silicon oxide, silicon oxynitride, silicon nitride, or any combination thereof.

The principles and advantages of sidewall spacers can be applied to a variety of applications in microelectronic devices. In some implementations, the sidewall spacers can reduce or eliminate cracking in inter level dielectrics between crossing conductive lines. This can, for example, reduce leakage current.

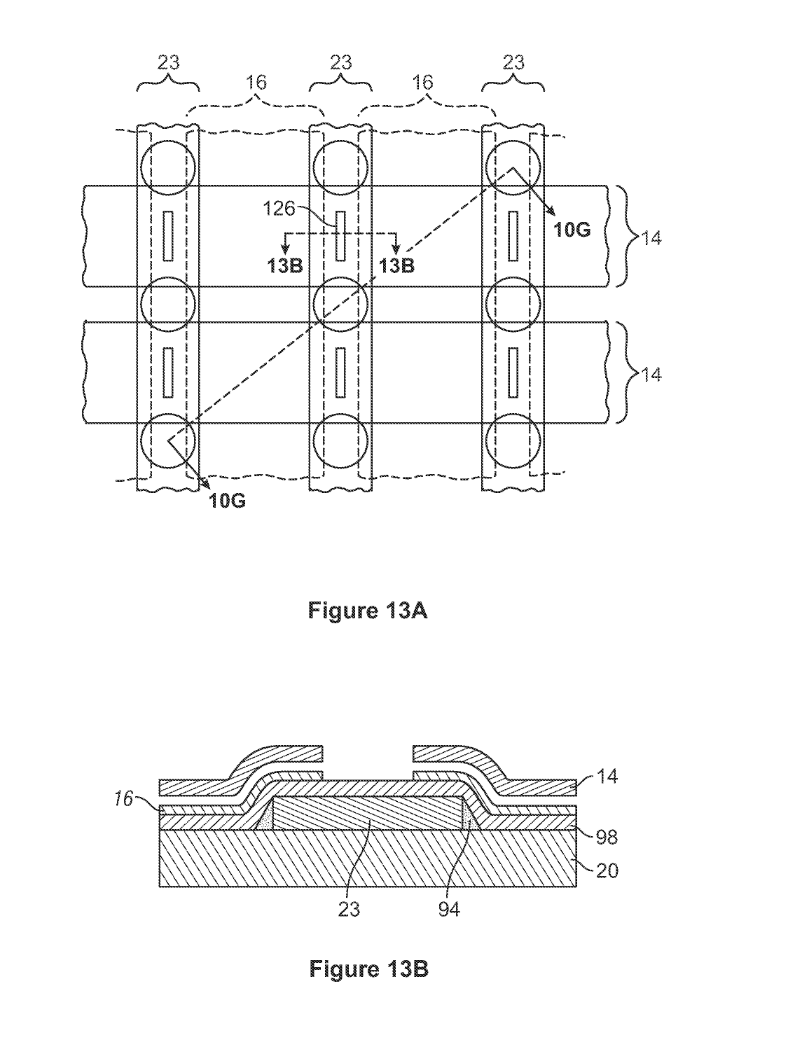

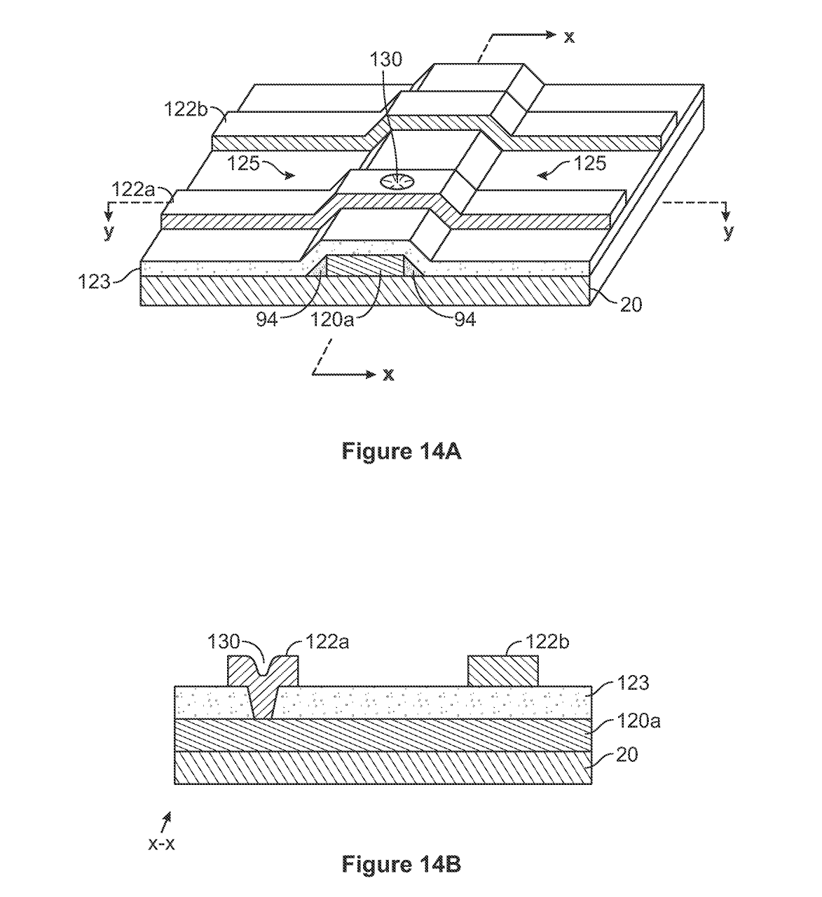

FIG. 13A shows an example of a schematic plan view of an interferometric modulator array that includes the interferometric modulators of FIG. 10G. The cross section of FIG. 10G is an example of a schematic cross section taken along the line 10G-10G of FIG. 13A. Columns of movable layers, such as movable reflective layers 14, and rows of stationary electrodes in the optical stack 16 can form IMOD pixels where they intersect. A movable layer cut 126 can be between neighboring IMOD pixels. At each pixel, the movable reflective layer 14 can be actuated between a relaxed position, in which the movable reflective layer 14 is supported above the stationary lower electrode of the optical stack 16, and an actuated position in which the movable reflective layer 14 contacts the optical stack 16.

In the implementation shown in FIG. 13A, the black mask structures 23 can include conductive bus lines configured to route electrical signals to IMODs in the IMOD array. Sidewall spacers 94 can be formed along sidewalls of the black mask structures 23, for example, as described earlier. Sidewall spacers 94 can be formed in a variety of locations. For instance, sidewall spacers can be formed in an anchor region adjacent to support structures configured to suspend a movable layer over a gap in a relaxed position. More specifically, the cross section of FIG. 13A taken along lines 10G-10G shows electromechanical systems devices with sidewall spacers as illustrated in FIG. 10G in an anchor region. Alternatively or additionally, sidewall spacers can be formed along sidewalls of a conductive line in other portions of an array of electromechanical systems devices. For example, a sidewall spacer can be included along a sidewall of a conductive line, at the location of lines 13B-13B, as will be described with reference to FIG. 13B.

The strips of movable reflective layers 14, and potentially other conductive lines (not illustrated in FIG. 13A) can be formed above lower conductive lines such as those represented by the black mask structures 23. Such upper conductive lines can have a number of orientations with respect to the black mask structure 23, such as being substantially parallel or substantially orthogonal to the black mask structure 23. The underlying topography can affect the upper conductive lines. Accordingly, sidewall spacers 94 can be formed along sidewalls of lower conductive lines, such as the black mask structures 23, to smooth the overlying topography.

FIG. 13B is an example of a schematic cross section taken along lines 13B-13B of FIG. 13A. FIG. 13B shows a schematic cross section along a conductive line away from the anchor region. The illustrated cross section is along a black mask bus line. A conductive line included in the black mask structure 23 can have sidewall spacers 94 along its sidewalls. The sidewall spacers 94 can reduce cusps or other undesirable topographies in layers formed over the conductive line and the substrate 20. For example, the buffer layer 98, the sacrificial layer 99 (not illustrated in FIG. 13B), and movable layer 14 can be formed with topographies that include an upward slope near an edge of the conductive line due to the sidewall spacer 94.

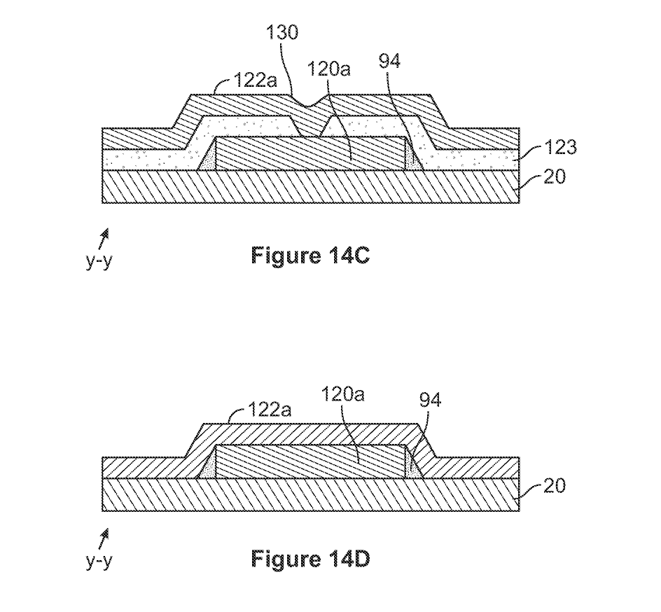

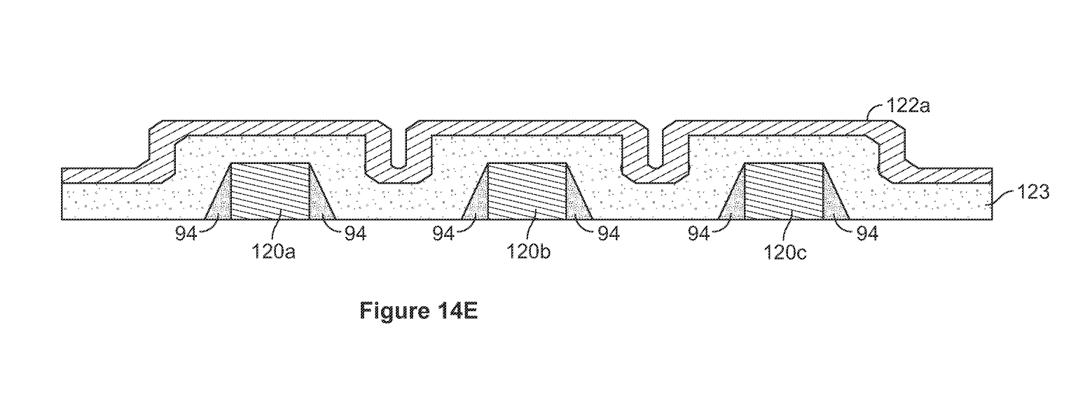

Sidewall spacers can be implemented along a sidewall of a line under another line in other contexts. FIG. 14A shows an example of a top isometric view of intersections of two conformal conductive lines formed over a lower conductive line. A lower conductive line 120a can be a single conductive line or can be one of a plurality of lower conductive lines. Upper conductive lines 122a and 122b can be included in a plurality of upper conductive lines. The conductive lines 120a, 122a and 122b can be formed over a substrate 20. As an example, the conductive lines 120a, 122a and 122b can be interconnects for electromechanical systems devices (such as MEMS) or other microelectronic devices, for example, in peripheral regions. For instance, the conductive lines 120a, 122a and 122b can be bus lines to route signals to electromechanical systems devices in an array of electromechanical systems devices. As shown in FIG. 14A, upper conductive lines 122a and 122b can be conformally formed over the lower conductive line 120a. Sidewall stringers do not occur in a region 125 between the two conformal upper conductive lines 122a and 122b. Without the sidewall spacers 94, it would be difficult to remove all of the metal from the corners of the lower conductive line 120a (and overlying insulating layer 123) in the region 125 in order to form the conductive lines 122a and 122b by patterning a blanket metal layer. Without the sidewall spacers 94, stringer shorts are more likely to occur in the region 125 even after patterning the upper conductive lines 122a and 122b. The sidewall spacers 94 can increase the likelihood of patterning the upper conductive lines 122a and 122b without residual sidewall stringers. As illustrated, the upper conductive line 122a can be electrically connected to conductive line 120a by a via in the overlying insulating layer 123. When the conductive line 122a is conformal, the connection through the via in the overlying insulating layer 123 can result in a dimple 130 on the surface of the upper conductive line 122a.

FIGS. 14B-E show different examples of schematic cross sections of the intersection of conductive lines according to some implementations

FIG. 14B shows an example of a schematic cross section of the stacked conductive lines taken along lines X-X of FIG. 14A according to some implementations, while FIG. 14C shows an example of a schematic cross section of the stacked conductive lines taken along lines Y-Y of FIG. 14A. FIG. 14D shows an example schematic cross section similar to that shown in FIG. 14C, but for an implementation without an insulation layer between the conductive lines. FIG. 14E shows an example schematic cross section that includes multiple lower conductive lines with an upper conductive line conformally formed over the multiple lower conductive lines.

Referring back to FIG. 14A, sidewall spacers 94 can avoid sidewall stringers in regions 125 between adjacent upper conductive lines 122a and 122b formed conformally over the lower conductive line 120a. Furthermore, as shown in the implementations illustrated in FIGS. 14C and 14E, sidewall spacers 94 can allow for better conformal deposition of the insulating layer 123 over the lower conductive lines 120a, which can reduce the likelihood of cracking and/or leakage paths through the insulating layer 123. The sidewall spacers 94 shown in FIGS. 14A-E can include any combination of features of the sidewall spacers described above, for example, with reference to FIGS. 10B-G. For instance, the sidewall spacers 94 can be formed from metal and/or dielectric material. In some implementations, a metal sidewall spacer 94 can bolster the conduction of a conductive line in physical contact with the sidewall spacer 94, for example, by reducing the resistance of the conductive line.

As shown in the implementation of FIG. 14B, the lower conductive line 120a can be isolated from the upper conductive line 122b by the insulating layer 123. As also shown in the implementation of FIG. 14B, the upper conductive line 122a can contact the lower conductive line 120a by a via through the insulating layer 123. The formation of the upper conductive line 122a into the via can form a dimple 130. FIG. 14C illustrates the upper conductive line 122a contacting the lower conductive line 120a in the via through the insulating layer 123, in a transverse cross section taken along lines Y-Y of FIG. 14A. In an alternate implementation from that shown in FIGS. 14A-14C, the upper conductive line 122a can be formed directly over the lower conductive line 120a to form a physical connection without a via, for example, as shown in FIG. 14D. One or more of the implementations shown in FIGS. 14A-E can be included with an array of electromechanical systems devices (e.g., an IMOD array) in peripheral interconnect regions of an electromechanical systems device, or in other wiring or interconnect regions of a microelectronic device (e.g., an integrated circuit). Sidewall spacers 94 can therefore allow the formation of a stack of one or more upper conductive lines conformally formed over one or more lower conductive lines without forming a planarization layer in between the lower and upper conductive lines.

With reference to FIG. 14E, in some implementations, a plurality of lower conductive lines 120a, 120b and 120c can have a pitch of less than 10 microns, for example about 9 microns. The width of each of the lower conductive lines 120a, 120b and 120c can be less than 5 microns, for example about 4.5 microns, with a spacing between each of the conductive lines 120a of less than about 4 microns, for example about 3.5 microns. In some implementations, such a fine pitch may not be easily formed by a wet etch and is instead formed by dry etching a metal conductive layer. The lower conductive lines 120a, 120b and 120c can have a thickness selected from the range of about 0.5 to 1 micron. The insulating layer 123 can also have a thickness selected from the range of about 0.5 to 1 micron. The upper conductive layer 122a can have a thickness selected from the range of about 30 to 100 nm. As illustrated in the implementation of FIG. 14E, different sidewall spacers 94 do not touch each other in a region 127. The sidewall spacers 94 can cover the sharp corner where the lower conductive lines 120a, 120b and 120c meets the substrate 20.

In the implementations of FIGS. 14B-E, sidewall spacers 94 are formed along sidewalls of at least one lower line 120a. Also shown in the illustrated implementations, at least one upper line 122a is non-parallel to the lower line 120a and can be included over the lower line 120a, such that the upper line 122a crosses over the lower line 120a. The upper line 122a can be conformal, as illustrated in FIGS. 14B-14E. A plurality of upper conductive lines 122a and 122b can be formed over a single lower conductive line 120a, for example, as shown in FIG. 14A. Alternatively or additionally, a plurality of lower conductive lines 120a, 120b and 120c can be formed under one or more upper conductive lines 122a for example, as shown in FIG. 14E. In some implementations, the lower line(s) 120a can be used to route electrical signals to an array of devices, for instance, to the black mask structure of an IMOD array. A conformal dielectric layer, such as the insulating layer 123, can be included over lower line 120a, for example, as shown in FIGS. 14B and/or 14C. The lower line 120a can be in electrical contact with the upper line 122a, for example, as shown in FIGS. 14C and/or 14D. In some implementations, the conductive lines can be spaced apart from adjacent lines by less than approximately 5 μm. The conductive line 120a can have a height of at least approximately 1,500 Å.

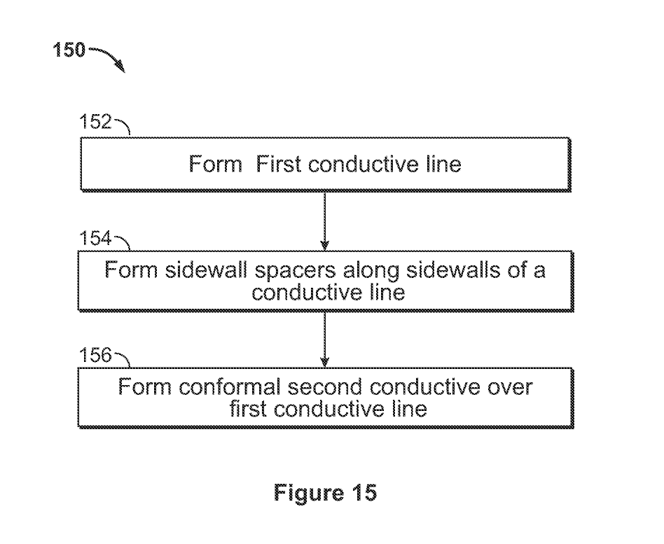

FIG. 15 shows an example of a flow diagram illustrating a manufacturing process 150 for conductive lines having sidewall spacers along sidewalls of the conductive lines, according to some implementations. A first conductive line extending along a first direction over a substrate is formed at block 152. At block 154, sidewall spacers are formed along sidewalls of the first conductive line. A second conductive line extending along a second direction over the first conductive line is formed at block 156. The second direction is non-parallel to the first direction. The second conductive line can be conformal. In some implementations, the first direction is substantially orthogonal to the second direction. In some implementations, two or more conformal second conductive lines are formed over the first conductive line by etching a single conformal conductive layer. The process 150 can include depositing a conformal dielectric layer over the first conductive line before block 156. In addition, the process 150 can also include forming an opening in the conformal dielectric to expose a top surface of the first conductive line, so that one or more of the second conductive lines contacts the first conductive line through the opening. Alternatively, one or more of the second conductive lines can be deposited directly over the first conductive line without an intervening dielectric layer. In some implementations, block 152 includes forming two or more first conductive lines.

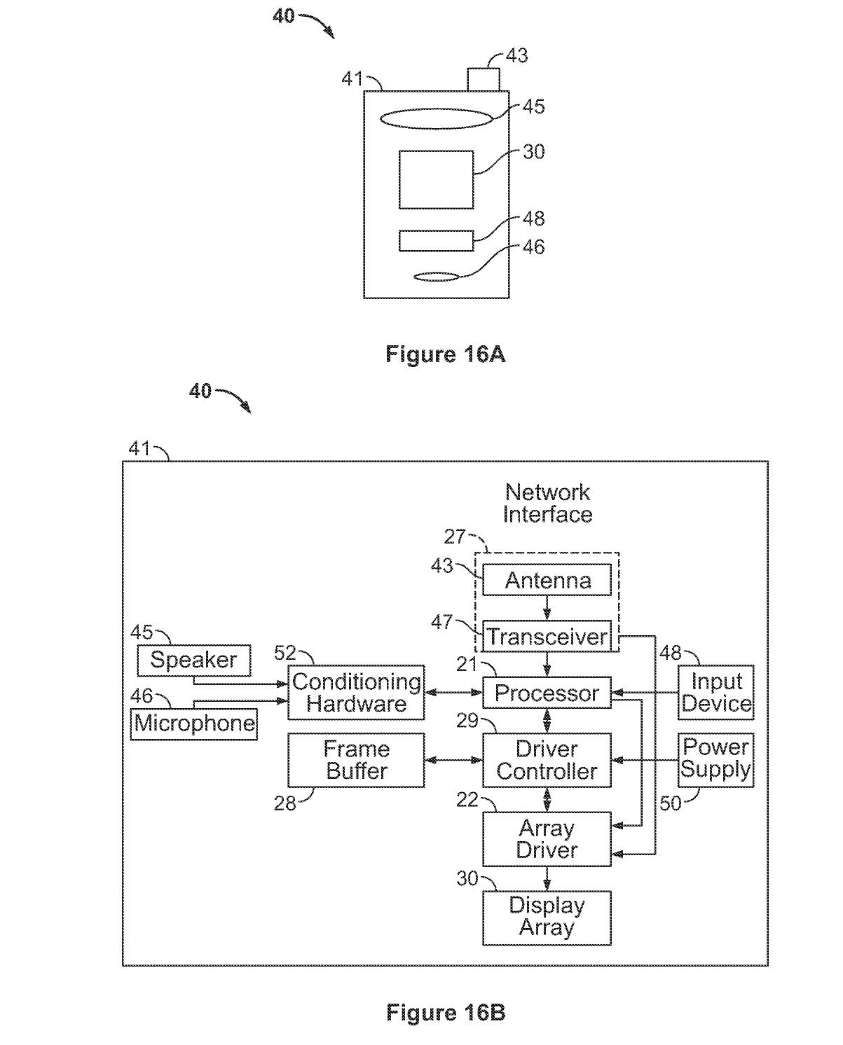

FIGS. 16A and 16B show examples of system block diagrams illustrating a display device 40 that includes a plurality of interferometric modulators. The display device 40 can be, for example, a smart phone, a cellular or mobile telephone. However, the same components of the display device 40 or slight variations thereof are also illustrative of various types of display devices such as televisions, tablets, e-readers, hand-held devices and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 16B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. In some implementations, a power supply 50 can provide power to substantially all components in the particular display device 40 design.

The network interface 27 includes the antenna 43 and the transceiver 47 so that the display device 40 can communicate with one or more devices over a network. The network interface 27 also may have some processing capabilities to relieve, for example, data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g, n, and further implementations thereof. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, in some implementations, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (such as an IMOD controller). Additionally, the array driver 22 can be a conventional driver or a bi-stable display driver (such as an IMOD display driver). Moreover, the display array 30 can be a conventional display array or a bi-stable display array (such as a display including an array of IMODs). In some implementations, the driver controller 29 can be integrated with the array driver 22. Such an implementation can be useful in highly integrated systems, for example, mobile phones, portable-electronic devices, watches or small-area displays.

In some implementations, the input device 48 can be configured to allow, for example, a user to control the operation of the display device 40. The input device 48 can include a keypad, such as a QWERTY keyboard or a telephone keypad, a button, a switch, a rocker, a touch-sensitive screen, a touch-sensitive screen integrated with display array 30, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices. For example, the power supply 50 can be a rechargeable battery, such as a nickel-cadmium battery or a lithium-ion battery. In implementations using a rechargeable battery, the rechargeable battery may be chargeable using power coming from, for example, a wall socket or a photovoltaic device or array. Alternatively, the rechargeable battery can be wirelessly chargeable. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits, algorithm steps, and manufacturing processes described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, such as a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification, including manufacturing processes, also can be implemented as one or more computer programs, i.e., one or more modules of computer program instructions, encoded on a computer storage media for execution by, or to control the operation of, data processing apparatus.

If implemented in software, the functions or processes may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blue-ray disc where disks usually reproduce data magnetically, while discs reproduce data optically with lasers. Combinations of the above also may be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other possibilities or implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of an IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, a person having ordinary skill in the art will readily recognize that such operations need not be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An apparatus comprising an electromechanical systems device, the electromechanical systems device including:
a substrate;
a conductive line over the substrate
a movable layer farther from the substrate than the conductive line; and
a sidewall spacer along at least one sidewall of the conductive line, wherein the sidewall spacer is sloped such that the sidewall spacer has a decreasing width away form the substrate.

2. The apparatus of claim 1, wherein the electromechanical systems device further includes an air gap between the movable layer and the conductive line.

3. The apparatus of claim 2, wherein the electromechanical systems device includes an active interferometric modulator pixel in which less than about 1.5% of light is reflected in a dark state occurring when the movable layer collapses on the air gap.

4. The apparatus of claim 1, wherein the conductive line is configured to route an electrical signal to the electromechanical systems device.

5. The apparatus of claim 1, wherein the conductive line is part of an interferometric black mask.

6. The apparatus of claim 1, wherein the width of the sidewall spacer decreases linearly away from the substrate.

7. The apparatus of claim 1, wherein the electromechanical systems device further includes a support structure positioned over the conductive line, the support structure supporting the movable layer.

8. The apparatus of claim 1, wherein the movable layer is shaped to be self-supporting.

9. The apparatus of claim 1, wherein the electromechanical systems device further includes a stand-off configured to prevent a backplate from contacting the movable layer.

10. The apparatus of claim 1, wherein the electromechanical systems device further includes a buffer formed over the sidewall spacer, wherein the buffer and the sidewall spacer each include one or more of silicon oxide, silicon oxynitride, and silicon nitride.

11. The apparatus of claim 1, wherein the movable layer includes a reflective surface configured to collapse on a gap.

12. The apparatus of claim 1, further including an other conductive line a having an other sidewall spacer along at least one sidewall, the other conductive line vertically displaced from the conductive line.

13. The apparatus of claim 12, wherein the other conductive line includes a bussing line.

14. The apparatus of claim 1, further including:
a display including an array of the electromechanical systems device;
a processor that is configured to communicate with the display, the processor being configured to process image data; and
a memory device that is configured to communicate with the processor.

15. The apparatus as recited in claim 14, further including:
a driver circuit configured to send at least one signal to the display; and
a controller configured to send at least a portion of the image data to the driver circuit.

16. The apparatus as recited in claim 14, further including:
an image source module configured to send the image data to the processor.

17. The apparatus as recited in claim 16, wherein the image source module includes at least one of a receiver, transceiver, and transmitter.

18. The apparatus as recited in claim 14, further including:
an input device configured to receive input data and to communicate the input data to the processor.

19. An apparatus comprising:
an electromechanical systems device including:
a conductive line formed over a substrate;
a movable layer suspended above the substrate, the movable layer having a first region over the conductive line and a second region not over the conductive line, wherein the first region is adjacent to the second region; and
means for smoothing a transition in the movable layer between the first region and the second region, the means for smoothing located along an edge of the conductive line.

20. The apparatus of claim 19, wherein the movable layer includes a mirror layer configured to collapse a gap under the movable layer.

21. The apparatus of claim 19, wherein the means for smoothing avoids a kink in the transition in the movable layer between the first region and the second region.

22. The apparatus of claim 19, wherein the means for smoothing creates a slope in the movable layer in the transition from the second region to the first region, wherein a distance between the movable layer and the substrate increases in the transition from the second region to the first region.

23. The apparatus of claim 19, wherein the second region is an active part of an interferometric modulator and the first region includes a black mask.

24. The apparatus of claim 19, wherein the means for smoothing includes a sidewall spacer along at least one sidewall of the conductive line.

25. A method of forming an electromechanical systems device, the method comprising:
forming a sidewall spacer along at least one sidewall of a conductive line, the conductive line over a substrate;
forming a sacrificial layer over the conductive line and the sidewall spacer;
forming a movable layer of the electromechanical systems device over the sacrificial layer.

26. The method of claim 25, wherein forming the sidewall spacer is performed while patterning an other feature of the electromechanical systems device.

27. The method of claim 26, wherein the other feature of the electromechanical systems device includes a stand-off that extends above the movable layer.

28. The method of claim 26, wherein the other feature of the electromechanical systems device is formed over the conductive line.

29. The method of claim 26, wherein forming the sidewall spacer includes:
depositing a blanket layer of material from which the sidewall spacer and the other feature will be formed; and
using a mask to cover a location of the other feature while leaving a location of the sidewall spacer exposed by the mask.

30. The method of claim 25, further including removing the sacrificial layer to create a gap under the movable layer.

31. The method of claim 25, further including forming a buffer layer over the conductive line and the sidewall spacer prior to forming the sacrificial layer.

32. The method of claim 25, further including forming a black mask including an absorber layer, a dielectric layer, and the conductive line.

33. An apparatus comprising:
a substrate;
a first line formed over the substrate;
sidewall spacers along sidewalls of the first line; and
a second line non-parallel to the first line, wherein the second line is conformally over the first line.

34. The apparatus of claim 33, wherein the first line is a conductive line.

35. The apparatus of claim 33, further including a conformal dielectric between the first line and the second line.

36. The apparatus of claim 33, wherein the first line is in electrical contact with the second line.

37. The apparatus of claim 33, further including a first plurality of lines and a second plurality of lines non-parallel to the first plurality of lines, the first plurality of lines including the first line, and the second plurality of lines including the second line.

38. The apparatus of claim 37, wherein each line of the first plurality of lines is a metal line and each line of the second plurality of lines is a metal line.

39. The apparatus of claim 37, wherein each line of the second plurality of lines is spaced apart from an adjacent line of the second plurality of lines by less than approximately 5 μm.

40. The apparatus of claim 33, wherein the sidewall spacers include metal.

41. The apparatus of claim 33, wherein the first line has a height of at least approximately 1,500 Å.

42. A method of forming a stack of conductive lines, the method comprising:
forming a first conductive line over a substrate;
forming sidewall spacers along sidewalls of the first conductive line; and
forming a second conductive line crossing over the first conductive line, wherein the second conductive line is conformal.

43. The method of claim 42, further including depositing a conformal dielectric layer over the first conductive line.

44. The method of claim 42, further including forming an opening in the conformal dielectric conformal layer to expose a top surface of the first conductive line.
